(19) United States
(12) Patent Application Publication
(10) Pub. No.: US 2026/0362758 A1
(43) Pub. Date: Nov. 12, 2026

(54) MOSFET WITH REDUCED GATE TO DRAIN CAPACITANCE

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/669,743

(22) Filed: May 6, 2026

Related U.S. Application Data
(60) Provisional application No. 63/801,592, filed on May 7, 2025.
(60) Provisional application No. 63/801,597, filed on May 7, 2025.
(60) Provisional application No. 63/801,603, filed on May 7, 2025.

(51) Int. Cl. H10D 62/10; H10D 30/66; H10D 64/27; H10D 64/68; H10D 30/01

(52) U.S. Cl. CPC H10D 62/102; H10D 30/668; H10D 62/124; H10D 64/516; H10D 64/518; H10D 64/681; H10D 30/0291; H10D 30/0297; H10D 30/66; H10D 64/685

(57) ABSTRACT

A metal oxide semiconductor field effect transistor (MOSFET) comprises a body, a drain, a source, a gate, a gate oxide, and an air gap. The body is formed from semiconductor material to present opposite, vertically spaced first and second ends. The source is positioned adjacent the second end of the body. A drift region is defined by the body between the source and the drain. The gate is positioned adjacent the second end of the body proximal to the source. The gate oxide is positioned in contact with the gate. The air gap is positioned within the gate oxide.

### CROSS-REFERENCE TO RELATED APPLICATIONS

The current patent application is a non-provisional utility patent application which claims priority benefit, with regard to all common subject matter, of earlier-filed U.S. Provisional Application Ser. No. 63/801,597, titled “TRENCH MOSFET WITH REDUCED GATE TO DRAIN CAPACITANCE”, and filed May 7, 2025; U.S. Provisional Application Ser. No. 63/801,603, titled “TRENCH MOSFET WITH REDUCED GATE TO DRAIN CAPACITANCE”, and filed May 7, 2025; and U.S. Provisional Application Ser. No. 63/801,592, titled “PLANAR MOSFET WITH REDUCED GATE TO DRAIN CAPACITANCE”, and filed May 7, 2025. The Provisional Applications are hereby incorporated by reference, in their entireties, into the current patent application.

### FIELD

Various examples of the current technology relate to trench-type and planar-type metal oxide semiconductor field effect transistors (MOSFETs) that have a reduced gate to drain capacitance and methods of fabricating MOSFETs that have a reduced gate to drain capacitance.

### Background

A metal oxide semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

The background discussion is intended to provide information related to the present technology which is not necessarily prior art.

### SUMMARY

Various examples of the current technology address one or more of the above-mentioned issues and provide trench-type and planar-type metal oxide semiconductor field effect transistors (MOSFETs) that have a reduced gate to drain capacitance which allow the MOSFETs to switch on and off at a higher frequency. The reduced gate to drain capacitance results, at least in part, from the presence of one or more air gap(s) in a gate oxide.

An example of the MOSFET may comprise a body, a drain, a source, a gate, a gate oxide, and an air gap. The body may be formed from semiconductor material to present opposite, vertically spaced first and second ends. The source may be adjacent the second end of the body, with a drift region being defined by the body between the source and the drain. The gate may be adjacent the second end of the body proximal to the source. The gate oxide may be in contact with the gate. The air gap may be within the gate oxide.

The preceding example may include any one or more of the following features.

The gate oxide may include a first oxide portion that is located between and contacts the gate and the drift region, and the air gap may be positioned in the first oxide portion of the gate oxide.

The drain may be located at the first end of the body. The first oxide portion and air gap may be located beneath the gate.

The gate oxide may include a second oxide portion that is located between and contacts the gate and the source.

The second oxide portion may be devoid of an air gap.

The MOSFET may include a trench extending from the second end into the body. The gate oxide may line the trench, and the gate may be positioned in the trench interiorly of the gate oxide.

The trench may include a trench bottom surface spaced from the second end of the body. The trench may further include laterally spaced apart left and right trench side surfaces, each of which extends between the trench bottom surface and the second end.

The first oxide portion may be located along the trench bottom surface.

The source may be located along the left trench side surface, and the second oxide portion may be located along the left trench side surface.

The MOSFET may include a well having an opposite dopant polarity than the source and being located along the left trench side surface beneath the source.

The source may include left and right source sections, each of being located along the respective trench side surface. The second oxide portion may be located along the left trench side surface and the right trench side surface. The well may be located along each of the trench side surfaces beneath the respective source section.

The trench may include a top trench section positioned at the second end of the body and a bottom trench section beneath the top trench section. The bottom trench section may have a lateral width that is less than a lateral width of the top trench section. The first oxide portion may be located in the bottom trench section.

Each of the trench sections may include laterally spaced apart left and right trench side surfaces, with the trench side surfaces of the top trench section extending from the second end of the body. The second oxide portion may be located along the left and right trench side surfaces of the top trench section.

The gate may be located in the top trench section. The gate oxide may include an oxide layer located within the top trench section. The oxide layer may underlie the gate and extend between the left and right trench side surfaces of the top trench section.

The second end of the body may be planar. The source may be located at the second end of the body. The drift region may extend to the second end of the body and be spaced laterally from the source. The gate may be located above the second end of the body.

The well may be located at the second end of the body between the source and the drift region. The second oxide portion may overlie the well and at least a portion of the source. The first oxide portion may extend laterally from the second oxide portion and overlie the drift region.

The air gap may include multiple, isolated portions.

The first oxide portion may be formed at least in part of a material having a first dielectric constant.

The second oxide portion may be formed of a material having a second dielectric constant.

The first dielectric constant may be less than second dielectric constant.

The trench may include a top trench section positioned at the second end of the body and a bottom trench section beneath the top trench section. The gate may be located in the top trench section. The air gap may be located in the bottom trench section. The bottom trench section may have a lateral width that is less than a lateral width of the top trench section.

The air gap may include less than five (5) total isolated portions, each of which has a minimum cross-sectional dimension of at least twenty nanometers (20 nm).

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current technology will be apparent from the following detailed description of the various examples and the accompanying drawing figures.

### BRIEF DESCRIPTION OF DRAWINGS

Various examples of the current technology are described in detail below with reference to the attached drawing figures, wherein:

FIG. 1 is a schematic cross-sectional view of a trench-type metal oxide semiconductor field effect transistor (MOSFET), constructed in accordance with various examples of the current technology and including a gate oxide having one or more air gap(s) to lower capacitance and provide reduced switching times;

FIG. 2 is a schematic cross-sectional view of a second example of the trench-type MOSFET;

FIG. 3 is a schematic cross-sectional view of a third example of the trench-type MOSFET;

FIG. 4 is a schematic cross-sectional view of a planar-type MOSFET including a gate oxide having one or more air gaps to lower capacitance and provide reduced switching times;

FIGS. 5A, 5B, 5C, 5D, 5E, 5F, 5G, 5H, 5I, 5J, 5K, 5L, 5M, 5N, 5O, 5P and 5Q, illustrate portions of the field effect transistor during a plurality of operations of a method for fabricating the trench-type MOSFET including a gate oxide having one or more air gap(s);

FIG. 6 includes a plurality of blocks listing of at least a portion of the operations of the method for fabricating the trench-type MOSFET including the gate oxide having one or more air gap(s);

FIGS. 7A, 7B, 7C, 7D, 7E, and 7F, illustrate portions of the field effect transistor during a plurality of operations of a method for fabricating the planar-type MOSFET including a gate oxide having one or more air gap(s); and

FIG. 8 includes a plurality of blocks listing of at least a portion of the operations of the method for fabricating the planar-type MOSFET including the gate oxide having one or more air gap(s).

The drawing figures do not limit the current technology to the specific examples disclosed and described herein. The drawings are not necessarily to scale, emphasis instead being placed upon clearly illustrating the principles of the technology.

### DETAILED DESCRIPTION

The following detailed description of the technology references the accompanying drawings that illustrate specific examples in which the technology can be practiced. The various examples are intended to describe aspects of the technology in sufficient detail to enable those skilled in the art to practice the technology. Other examples can be utilized and changes can be made without departing from the scope of the current technology. The following detailed description is, therefore, not to be taken in a limiting sense. The scope of the current technology is defined only by the appended claims, along with the full scope of equivalents to which such claims are entitled. In addition, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In the following description, the word “voltage” may be used to describe electric voltage, the word “current” may be used to describe electric current, and the word “power” may be used to describe electric power. Relational and/or directional terms, such as “above,” “below,” “up,” “upper,” “upward,” “down,” “lower,” “downward,” “top,” “bottom,” “outer,” “inner,” “left,” “right,” etc., along with orientation terms, such as “horizontal” (or lateral) and “vertical,” may be used throughout this description. These terms retain their commonly accepted definitions and are used with reference to examples of the technology and the positions, directions, and orientations thereof shown in the accompanying figures. However, examples of the technology in practice may be positioned and oriented in other ways or move in other directions. Therefore, the terms do not limit the scope of the current technology.

Metal oxide semiconductor field effect transistors (MOSFETs) generally comprise a semiconductor body that includes a gate, a source, and a drain. Silicon (Si) is typically used as the semiconductor material, although in high voltage applications, silicon carbide (SiC) is utilized. The drain may be positioned at a first end of the body (although alternative locations are contemplated according to certain examples discussed herein), and the source is positioned at a second, opposing end of the body, with a drift region positioned therebetween. The gate is typically positioned in proximity to the source. In a trench-type MOSFET, the gate extends alongside the source and is positioned within a trench, or cavity, in the body. In a planar-type MOSFET, there is no trench, and the gate is positioned above the source and the well at the second end of the body. Furthermore, a gate oxide, formed from or including dielectric or electrically insulating material, is positioned between the gate and the body. Given the structure of the gate, the gate oxide, and the drain, a capacitor between the gate and the drain, Cgd, exists.

During operation of the MOSFET, applying voltage to the gate at a first voltage level allows for increased current flow in the drift region, which switches the MOSFET on. Applying voltage to the gate at a second voltage level results in decreased current flow in the drift region, which switches the MOSFET off. A period of time to switch the MOSFET on (which may be considered charging the gate-drain capacitor Cgd) and a corresponding period of time to switch the MOSFET off (which may be considered discharging the gate-drain capacitor Cgd) vary according to a value of a capacitance of the structural combination. In a simplified form, an equation to determine the switch on time and the corresponding switch off time of the MOSFET is given as: t = C×R, wherein t is the time (in seconds), C is the capacitance of the structural combination, and R is a resistance of circuitry used to apply voltage to the gate. Thus, the switching time of the MOSFET may be reduced by reducing the capacitance of the gate-drain capacitor Cgd.

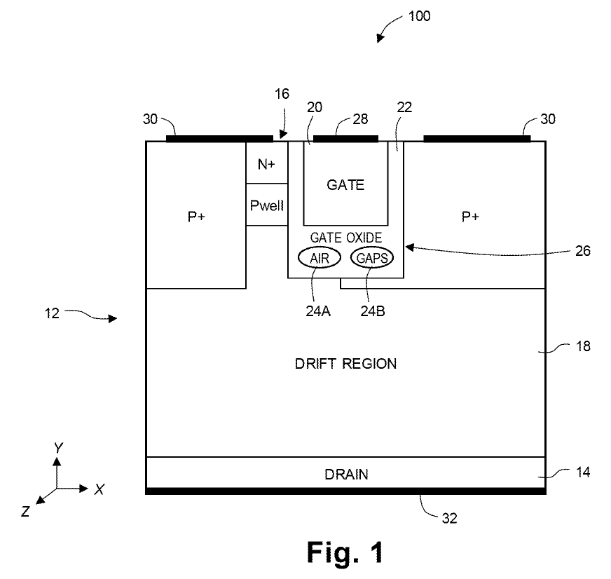

Referring to FIGS. 1-4, examples of an improved MOSFET 100, 200, 300, 400 are shown. First, second, and third examples of the MOSFET 100, 200, 300 are trench-type MOSFETs, and a fourth example of the MOSFET 400 is a planar-type MOSFET. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. The MOSFET 100, 200, 300, 400 broadly comprises a body 12, a drain 14, a source 16, a drift region 18, a gate 20, a gate oxide 22, and one or more air gap(s) 24. Some examples of the MOSFET 100, 200, 300 further comprise a trench 26. In addition, the MOSFET 100, 200, 300, 400 includes a plurality of electrodes.

The body or volume of semiconductor material 12 presents a first (or bottom) end, a second (or top) end opposite and vertically spaced (along a Y dimension or direction when viewing FIG. 1) from the first end, a first (or left) side, and a second (or right) side opposite and laterally spaced (along an X dimension) from the first side. In addition, the body 12 may have a front end and a back end opposite and axially spaced (along a Z dimension) from the front end. The body 12 may be formed from or include an N- epitaxial (epi) semiconductor material.

It will also be appreciated that the sides of the illustrated body 12 are defined herein merely to represent a portion of a larger volume of semiconductor material relative to the illustrated MOSFET 100, 200, 300, 400. In practice, the body 12 may extend laterally beyond the bounds illustrated in the drawings (leftward and rightward along the X dimension) to present additional semiconductor material in which additional devices may be provided. Such additional devices may be other MOSFETs 100, 200, 300, 400 or may be entirely different devices providing different operations or functions than the MOSFET 100, 200, 300, 400. In other words, although only one instance of a device may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right and/or left side of the body 12 may be to the conceptual limit of a particular unit cell and not to an actual physical end of the material.

The drain 14 is positioned at the first (bottom) end of the body 12, although in some aspects the drain 14 may be located elsewhere on the body 12 (such as the same (or second) end as the source 16). In the illustrated example, the drain 14 has a layer that is formed from or includes N+ material.

The source 16 is positioned at the second (top) end of the body 12. In examples of the MOSFET 100 with reference to FIG. 1, the source 16 may be positioned on the left side of the body 12 and may be formed from or include a heavily doped material of a first polarity type, i.e., N or P. In an example shown, the source is formed from or includes an N+ region. A well (preferably formed from or including P material) is located below and adjacent (particularly in contact with) the source 16. The source 16 and the adjacent well are located between the gate and an adjacent first doped region or body contact (preferably formed from or including a P+ material). A doped region is positioned on the right side of the body 12 and preferably includes a P+ material. It will be appreciated that, based upon this configuration, the MOSFET 100 is a single channel MOSFET.

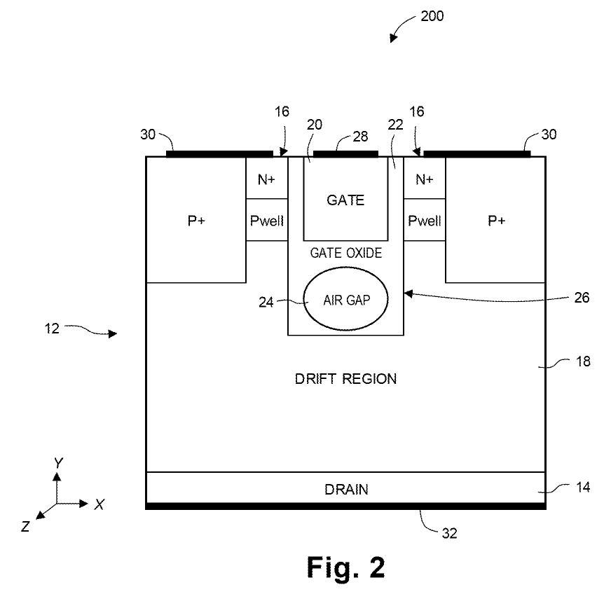

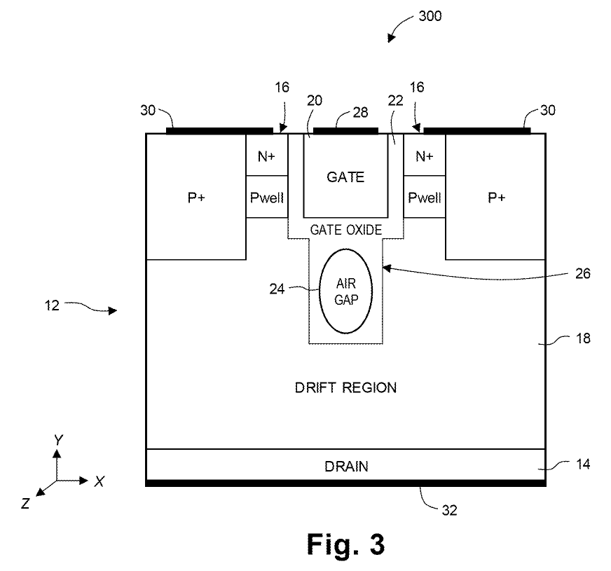

In examples of the MOSFET 200, 300 with reference to FIGS. 2 and 3, the source 16 may generally be split into two (2) sections positioned at the left and right sides of an upper region of the body 12. A first source section is positioned on the left side of the body 12 and may include a first N+ region. An adjacent first well (which may be formed from or include P material) is located between the first source section and the drift region 18. A first doped region or body contact (which may be formed from or include P+ material) is positioned alongside the first source section and the adjacent first well. A second source section is positioned on the right side of the body 12 and may include a second N+ region. An adjacent second well (which may be formed from or include P material) is located between the second source section and the drift region 18. A second doped region or body contact (which may be formed from or include P+ material) is positioned alongside the second source section and the adjacent second well. These examples are so-called dual channel MOSFETs. In the illustrated example, the MOSFET 100, 200, 300 (including the sources, wells, and doped regions) is symmetric about the vertical centerline of the trench 26 so that one side is the mirror image of the other. However, according to certain aspects, the first side transistor components (including the first source section, first well, and first body contact) and the second side transistor components (including the second source section, second well, and second body contact) may be differently configured.

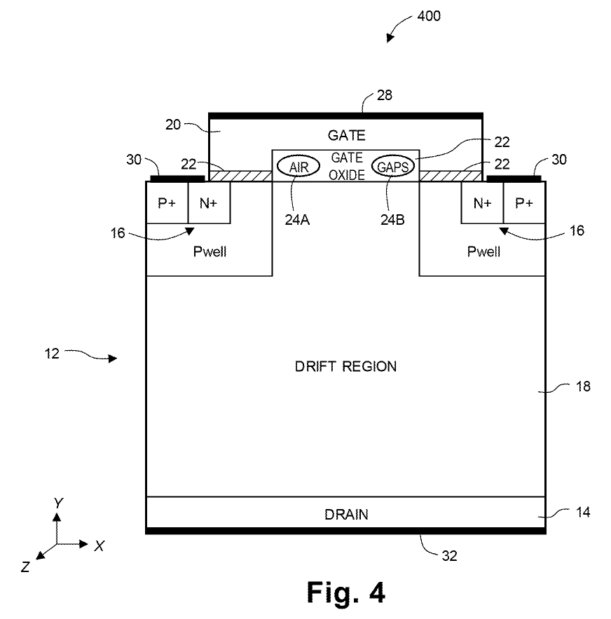

In examples of the MOSFET 400 with reference to FIG. 4, the source 16 may generally be split into two (2) sections positioned adjacent the left and right sides of an upper region of the body 12. A first source section is positioned on the left side of the body 12 and includes an N+ material, and a second source section is positioned on the right side of the body 12 and includes an N+ material. Left and right wells are provided adjacent (particularly in contact with) the respective first and second source sections. A body contact (or doped region) is located at the second end on the opposite side of the respective source section from the well. The body contact may be formed from or include P+ material and the well may be formed from or include P material. Each well extends from the second of the body 12 at a location inwardly (closer to the center of the MOSFET 400) from the respective source section and also underlies the respective source section and body contact. It will be appreciated that the second end of the body 12 is planar (devoid of a trench), with the gate 20 and gate oxide 22 being located above (and overlying) the second end (specifically the well and part of the source 16), such that a planar MOSFET 400 is depicted in the FIG. 4 In the illustrated embodiment, the MOSFET 400 side structures (each comprising the corresponding source section, well, and doped region) are mirror images of one another, although side structures having different configurations are within the ambit of certain aspects of the example MOSFET 400. However, according to certain aspects, the first side transistor components (including the first source section, first well, and first body contact) and the second side transistor components (including the second source section, second well, and second body contact) may be differently configured.

The drift region 18 generally provides a pathway for majority charge carrier movement and electric current flow between the source 16 and the drain 14. In examples of the MOSFET 100 with reference to FIG. 1, the drift region 18 is positioned beneath the left doped region and the first well (just below the source 16), the trench 26, and the right doped region. The drift region 18 extends to the sides of the body 12 as well as an upper edge of the drain 14. The drift region 18 may be formed from or include N-doped epitaxial (epi) material. The drift region 18 may include a channel of charge carrier flow that forms toward the left side of the body 12 between the source 16 and the drain 14.

In examples of the MOSFET 200, 300 with reference to FIGS. 2 and 3, the drift region 18 is positioned beneath the trench 26 and the first and second doped regions and wells. The drift region 18 extends to the sides of the body 12 as well as an upper edge of the drain 14. The drift region 18 may be formed from or include N-doped epitaxial (epi) material. The drift region 18 may include a first channel of charge carrier flow that forms toward the left side of the body 12 between the first section of the source 16 and the drain 14 and a second channel of charge carrier flow that forms toward the right side of the body 12 between the second section of the source 16 and the drain 14.

In examples of the MOSFET 400 with reference to FIG. 4, the drift region 18 is positioned beneath and between the first and second sections of the source 16, the wells, and the body contacts, and extends to the sides of the body 12 as well as an upper edge of the drain 14. The drift region 18 may be formed from or include N-doped epitaxial (epi) material. The drift region 18 may include a first channel of charge carrier flow that forms toward the left side of the body 12 between the first section of the source 16 and the drain 14. As depicted, the drift region 18 may also include a second channel of charge carrier flow that forms toward the right side of the body 12 between the second section of the source 16 and the drain 14. Therefore, a dual channel MOSFET 100 is shown.

The MOSFET 100, 200, 300 includes the trench 26 which comprises a cavity or recess positioned at the second, or top, end of the body 12. The trench 26 extends into the body 12 and has spaced-apart left and right side surfaces, with a bottom surface positioned therebetween at an orthogonal angle to the side surfaces. In examples of the MOSFET 100 with reference to FIG. 1, a portion of the left side surface is adjacent to the left doped region (body contact), the well, and the source 16. More particularly, the source 16 and well extend along the left side surface of the trench 26. The right side surface and a portion of the bottom surface are adjacent to the right doped region. More particularly, the right doped region extends along the left side surface and part of the bottom side surface of the trench 26. Those ordinarily skilled in the art will appreciate that the right doped region (particularly the portion underlying the trench 26) acts as a “shield” to protect the gate oxide 22 from the field. In examples of the MOSFET 200, 300 with reference to FIGS. 2 and 3, a portion of the left side surface is adjacent to the first section of the source 16. More particularly, the first (or left) sections of the source 16 and well extend along the left side surface of the trench 26. A portion of the right side surface is adjacent to the second section of the source 16. More particularly, the second (or right) sections of the source 16 and well extend along the right side surface of the trench 26. The depth (along the Y dimension) of the trench 26 may be less than or equal to half a height of the body 12, although other aspects of the example MOSFET 100, 200, 300 contemplate an alternative trench depth that is tuned according to the particular application.

In addition, the trench 26 of the MOSFET 300, with reference to FIG. 3, includes a top section and a bottom section. The top section includes a first left side surface, a first right side surface, and a first bottom surface including left side and right side (or shoulder) sections. The top section has a first width (along the X dimension). The bottom section is positioned beneath the top section, extending into the drift region 18, and includes a second left side surface, a second right side surface, and a second bottom surface. The bottom section has a second width (along the X dimension) that is less than the first width.

The gate 20 generally has a voltage applied to it that turns the MOSFET 100, 200, 300, 400 on and off according to a level of the voltage. That is, at a first voltage level, the MOSFET 100, 200, 300, 400 is turned on, and at a second voltage level, the MOSFET 100, 200, 300, 400 is turned off. In examples of the MOSFET 100, 200, 300 with reference to FIGS. 1, 2, and 3, the gate 20 has a generally rectangular cuboid shape with a top surface, left and right side surfaces, and a bottom surface. The gate 20 is positioned at the second, or top, end of the structure of the body 12 within the trench 26 – above an upper edge of the drift region 18. In FIGS. 1-3, the gate 20 is depicted as filling the trench interiorly of the gate oxide 22, although certain alternative examples contemplate a portion(s) of the gate being replaced with other structure (such as the electrode 28). In examples of the MOSFET 400 with reference to FIG. 4, the gate 20 includes a top wall, a left side wall, and a right side wall. The top wall has an upper surface and a lower surface. The left side wall is continuous with and extends downward from a left portion of the lower surface of the top wall, and the right side wall is continuous with and extends downward from a right portion of the lower surface of the top wall. The downward extension of the left and right side walls creates the boundaries for a space underneath the top wall adjacent to the lower surface. The gate 20 is positioned above the second, or top, end of the structure of the body 12 such that the left side wall is above portions of the first section of the source 16 and the left well, the right side wall is positioned above portions of the second section of the source 16 and the right well, and the top wall is positioned above an upper edge of the drift region 18. The gate 20 is formed from or includes polysilicon, a metal or alloy of metals, or other suitable material.

The gate oxide 22 provides electrical insulation (very high resistance) between the gate 20 and the drift region 18 and is, thus, positioned therebetween. The gate oxide 22 also cooperates with the adjacent (contacting) well to define an interface along which the respective channel is formed. In examples of the MOSFET 100, 200 with reference to FIGS. 1 and 2, the gate oxide 22 is positioned in the trench 26 and includes a left side section, a right side section, and a bottom section. The left side section, or left side wall, of oxide extends along the left side surface of the trench 26 in abutting engagement with the left side surface of the gate 20, the source 16, and the well. The right side section, or right side wall, of oxide extends along the right side surface of the trench 26 in abutting engagement with the right side surface of the gate 20 and the P+ doped region. The bottom section, or bottom wall, of oxide extends along a bottom surface of the trench 26 in abutting engagement with a bottom surface of the gate 20 and the drift region 18. It is further noted that the bottom section of the oxide 22 is preferably thicker (in the Y direction) than the left and right side sections (in the X direction), which is particularly beneficial in a MOSFET with the drain 14 located at the first end (as shown) in reducing the gate-drain capacitance.

In examples of the MOSFET 300 with reference to FIG. 3, the gate oxide 22 includes a top oxide section and a bottom oxide section. The top oxide section includes a left side wall and a right side wall. The left side wall extends along the first left side surface of the top section of the trench 26 and is in abutting engagement with the left side surface of the gate 20, the left source section 16, and the left well. The right side wall extends along the first right side surface of the top section of the trench 26 and is in abutting engagement with the right side surface of the gate 20, the right source section 16, and the right well. Because of the shoulders at the bottom of the top trench section (which result from the undercuts created by the narrower bottom trench section), each oxide side wall may include a bottom tab at a bottom edge thereof, with the tab extending inward underneath the gate 20 towards a lateral center of the trench 26. The bottom section of the gate oxide 22 is positioned within the bottom section of the trench 26, underneath the gate 20, and has a generally rectangular cuboid shape with a width that is less than the width of the gate 20.

In examples of the MOSFET 400 with reference to FIG. 4, the gate oxide 22 includes a middle oxide section, a left side oxide section, and a right side oxide section. The middle oxide section has a greater thickness (along the Y dimension) than the left and right side oxide sections and is positioned in the space between the top wall of the gate 20 and the upper edge of the drift region 18. The middle oxide section may be referred to herein as the thick oxide section, and the left and right side oxide sections may be referred to herein as the thin oxide sections. The left and right thin oxide sections may have the same approximate thickness, although certain aspects of the example MOSFET contemplate the left and right oxide sections having different thicknesses. The left side thin oxide section is positioned between the left side wall of the gate 20 and the well and a portion of the first section of the source 16. The right side thin oxide section is positioned between the right side wall of the gate 20 and the well and a portion of the second section of the source 16.

In each example shown in FIGS. 1-4, one or more of the section(s) of the gate oxide 22 may be formed from or include material that has a low dielectric constant “k.” Such material may include, for example, porous silicon dioxide (SiO2), fluorine-doped silicon oxide (SiOF), carbon-doped silicon oxide (SiCOH), organosilicate glass (OSG), silsesquioxanes (SSQ), and various spin-on organic polymers like polyimide, polynorbornenes, and benzocyclobutene; all of which achieve low dielectric constant values by introducing porosity or specific chemical modifications. The dielectric constant k may have a value of less than or approximately equal to four (4).

As an example, the MOSFET 100 of FIG. 1 may include a low k material in the bottom section of the gate oxide 22. More particularly, the low k material may be provided just above the air gaps 24A, 24B. In the illustrated MOSFET 100, the left and right side sections of dielectric 22 are devoid of low k material. However, other examples contemplate the low k material being alternatively or additionally provided elsewhere within the oxide 22, such as below the air gaps 24A, 24,B or in other sections (the left side section and/or right side section) of the oxide 22.

The term air gap(s) (or airgap(s)) 24 as used herein shall be interpreted to mean a single opening or a small number of intentionally formed openings in the gate oxide 22 (not countless randomly shaped, sized, and located openings, such as pores). The airgap(s) 24 have a specified shape, size, and location. The air gap(s) also have a minimum size so as to provide the desired dielectric constant to the oxide 22. The minimum cross-sectional dimension of the airgap(s) 24 may be five nanometers (5 nm) but may range up to five hundred nanometers (500 nm), with larger sizes, such as greater than twenty nanometers (20 nm), greater than one hundred nanometers (100 nm), and greater than two hundred fifty nanometers (250 nm), often being selected to achieve the desired dielectric constant. Again, the airgap size within this range is not sporadic or randomly created but is highly controlled and limited to the specified size (within acceptable tolerances) during the fabrication process. As will be described, certain examples contemplate an air gap 24 comprising a single opening or a pair of spaced apart, isolated openings (or portions air gap portions). According to some alternative examples, more air gaps 24 may be provided, although the number of air gaps in the oxide 22 is less than five (5). Each air gap 24 may be a cavity or chamber filled with a gas. In the illustrated examples, each air gap 24 contains atmospheric or ambient air. According to certain alternative examples, however, the air gap 24 may be filled with a specified single gas or mixture of gases (e.g., one or more inert gases). In some examples, the air gap 24 may be subjected to a vacuum during formation so as to be substantially evacuated and to consequently contain a significantly minimized amount of gas.

The air gap 24 provides a (relatively low) dielectric constant “k” of approximately one (1). In examples of the MOSFET 100 with reference to FIG. 1, a first air gap 24A and a second air gap 24B are positioned spaced apart from one another in the bottom section of the gate oxide 22. In examples of the MOSFET 200, 300 with reference to FIGS. 2 and 3, a single air gap 24 is positioned in the bottom section of the gate oxide 22. With reference to FIG. 4, the MOSFET 400 is a planar device (rather than a trench MOSFET as shown in FIGS. 1-3) and the first air gap 24A and the second air gap 24B are positioned spaced apart from one another in the thick oxide section of the gate oxide 22. In each example of the MOSFET 100, 200, 300, 400, there may be one maximally-sized air gap 24 positioned in the gate oxide 22, or there may be a plurality of smaller air gaps 24 positioned in the gate oxide 22 (with the smaller examples still falling with the definition of air gap 24 above).

More specifically, it is noted that the air gap 24 in the illustrated examples is located in the bottom section of the oxide 22 and not the left and right side sections. That is to say, the illustrated side sections of oxide are devoid of an air gap, although certain alternative examples contemplate one or both the side sections having an air gap if a reduced dielectric constant is desired. It is also noted that positioning of the air gap 24 in the bottom oxide section (underlying the gate 20) is beneficial with the illustrated embodiments, because the drain 14 is located at the first (bottom) end of the body 12. Additional or alternative locations of the air gap 24 may be desirable, particularly if the drain is positioned elsewhere along the body 12.

The electrodes provide electrical contact between various components of the MOSFET 100, 200, 300, 400 and bond wires that connect to a package for the MOSFET 100, 200, 300, 400. Specifically, the MOSFET 100, 200, 300, 400 includes a gate electrode 28 to provide electrical contact with the gate 20, a source electrode 30 to provide electrical contact with the source 16, and a drain electrode 32 to provide electrical contact with the drain 14. Each electrode 28, 30, 32 is formed from or includes metals or metal alloys.

The capacitance of the gate-drain capacitor Cgd may be given by the following equation: Cgd = (k×ε0×A)/t, wherein “k” (or “κ” (kappa)) is the dielectric constant, “ε0” is the permittivity of free space, “A” the area (length × width) of the overlap of the bottom surface of the gate 20 with the upper edge of the drift region 18, and “t” is a thickness of the bottom section or the middle (thick) oxide section of the gate oxide 22. The dielectric constant k is typically a property of the gate oxide 22, or in this case, the bottom or middle section of the gate oxide 22 (i.e., the portion of dielectric material extending between and contacting the gate 20 and drift region 18). But, having the air gap(s) 24 positioned in the bottom or middle section of the gate oxide 22 means that the dielectric constant k is the property of the combination of the air gap(s) 24 and the bottom or middle section of the gate oxide 22. The dielectric constant of air is less than the dielectric constant of the already low dielectric constant material of the bottom or middle section of the gate oxide 22. Thus, having the air gap(s) 24 in the bottom or middle section of the gate oxide 22 significantly reduces the capacitance of the gate-drain capacitor Cgd, which in turn, allows the MOSFET 100 to switch on and off at a higher frequency.

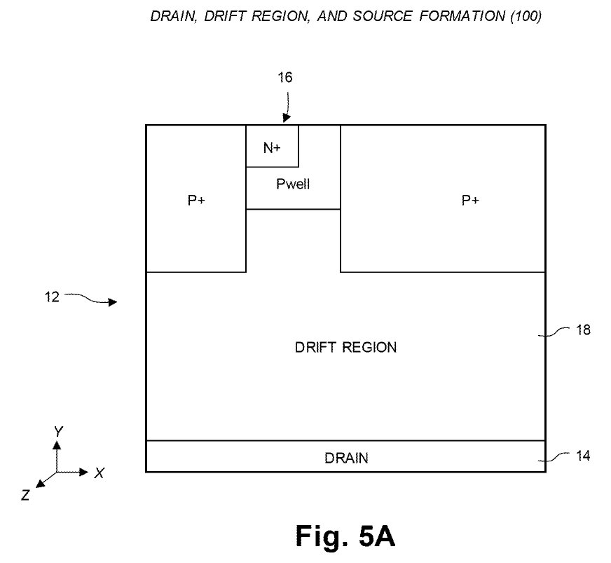

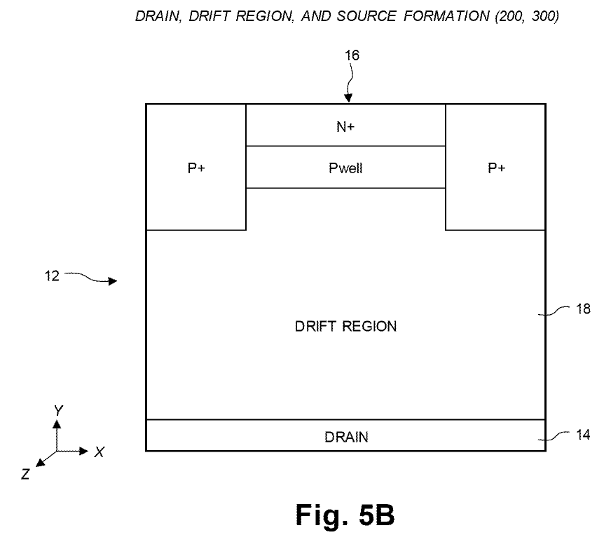

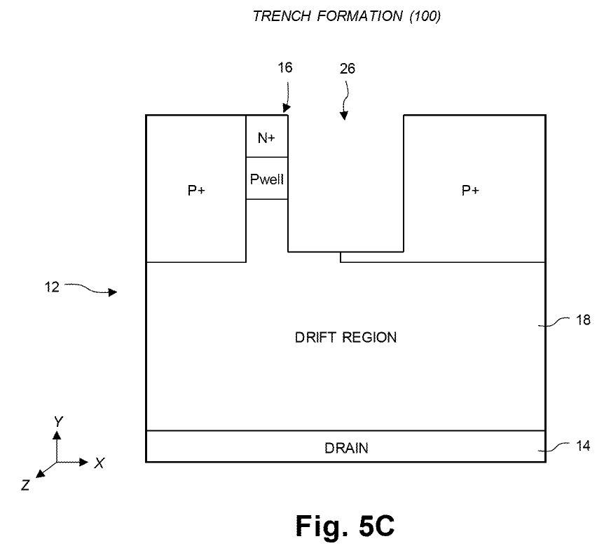

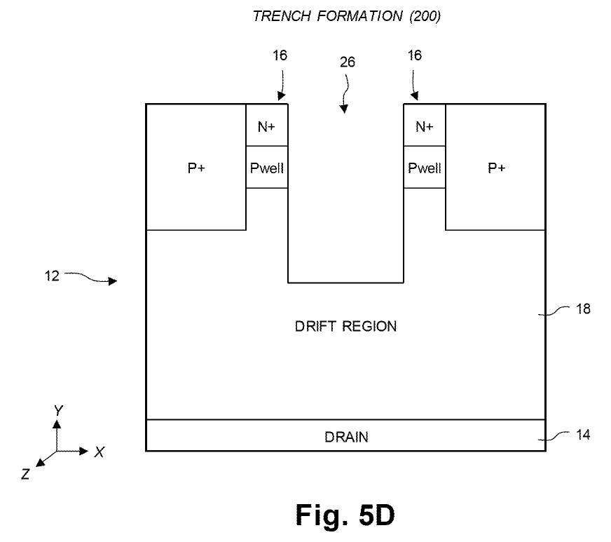

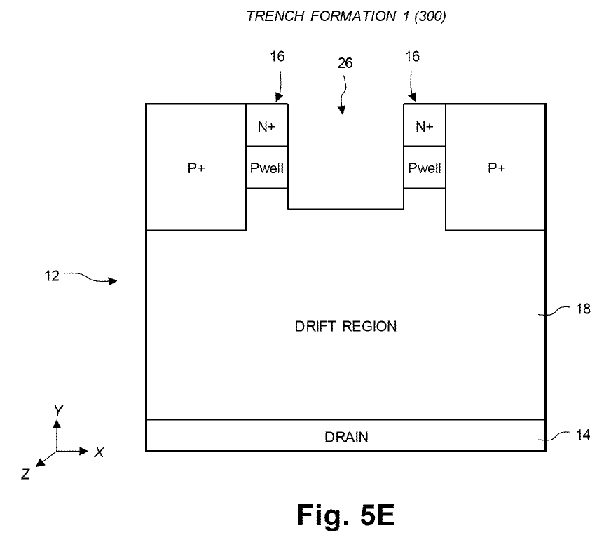

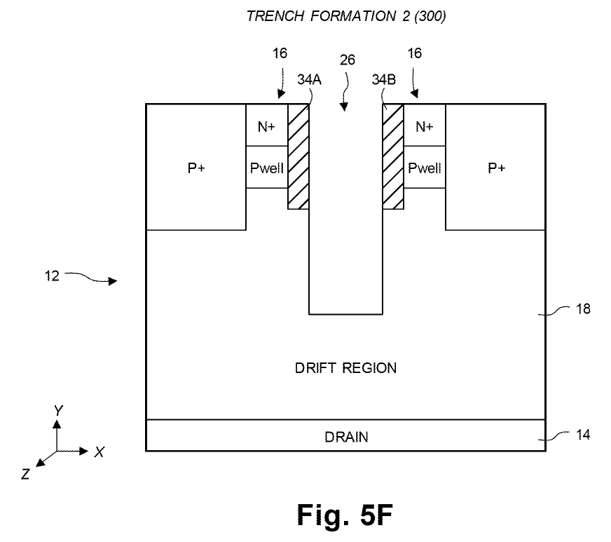

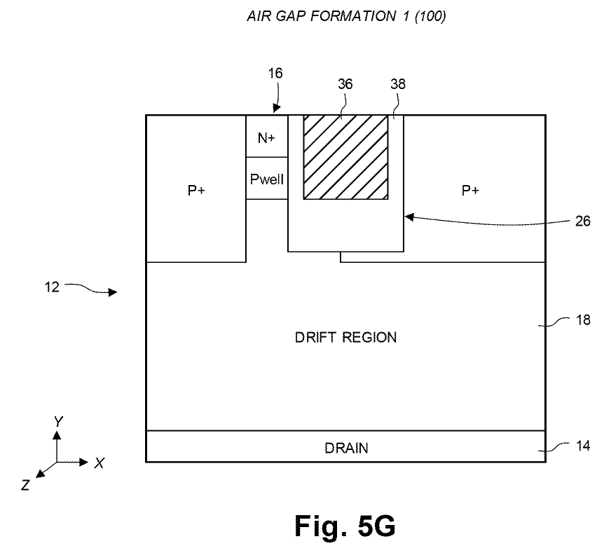

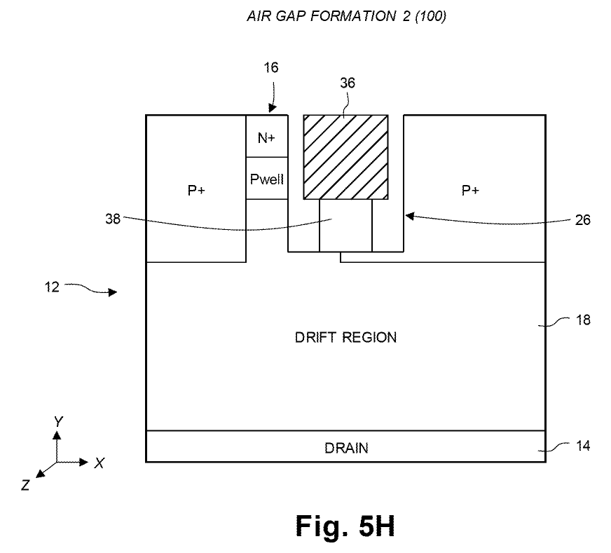

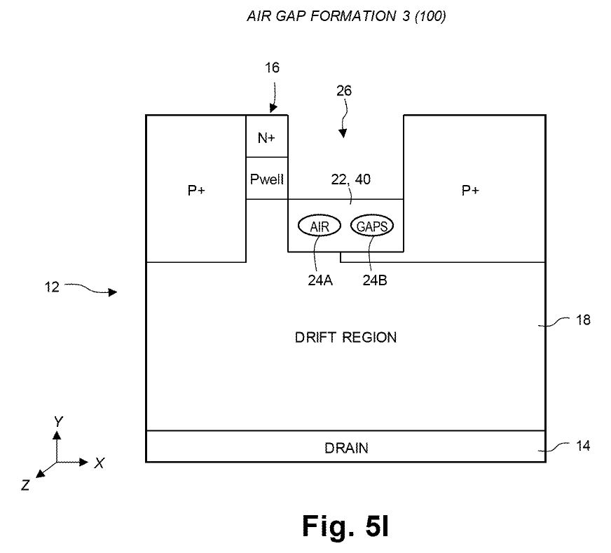

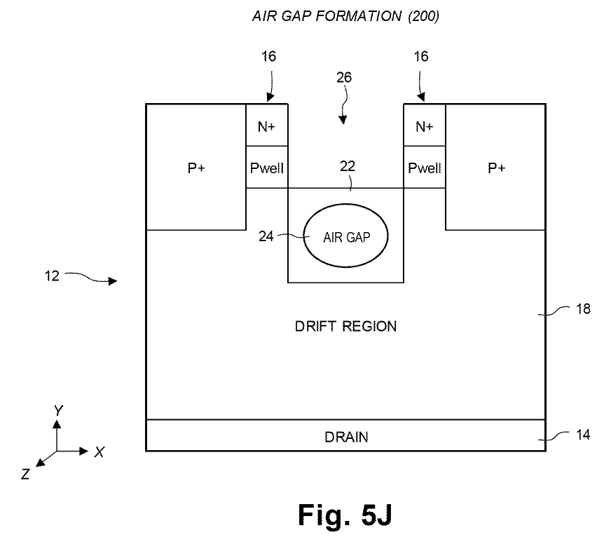

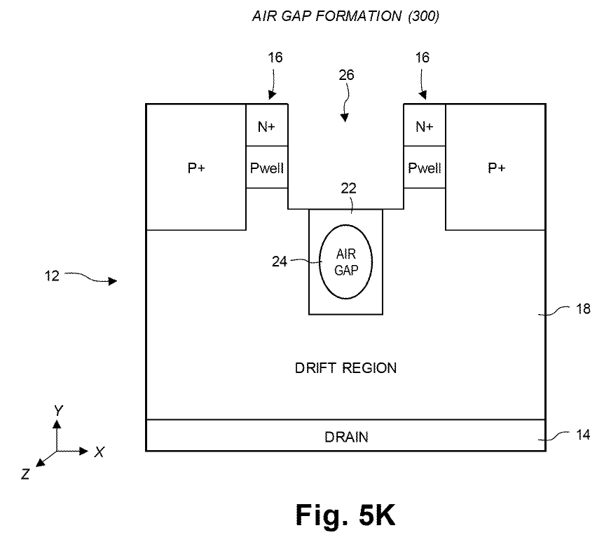

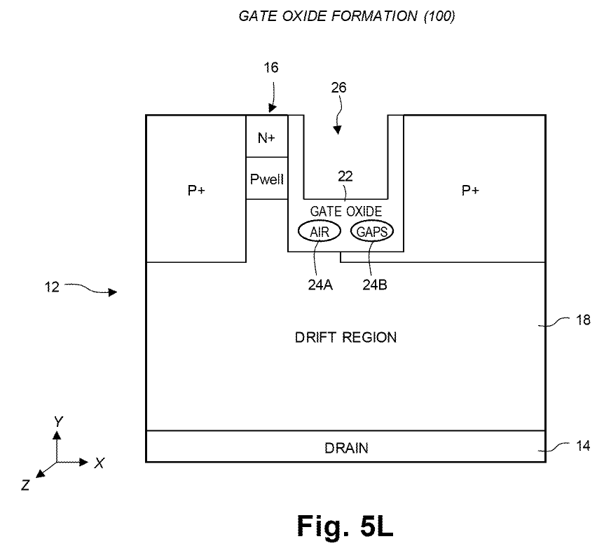

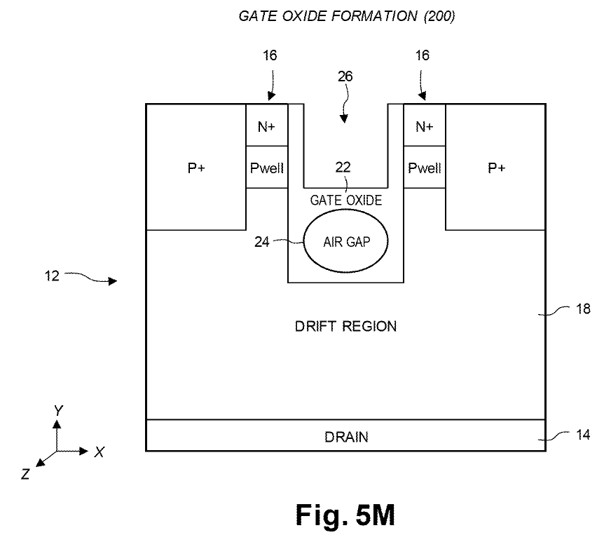

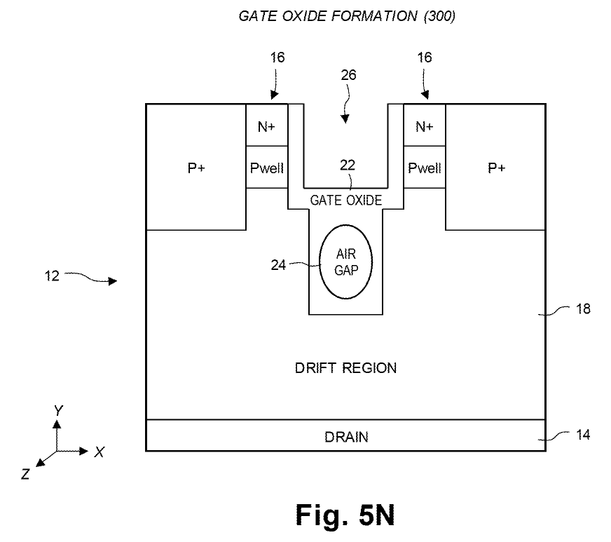

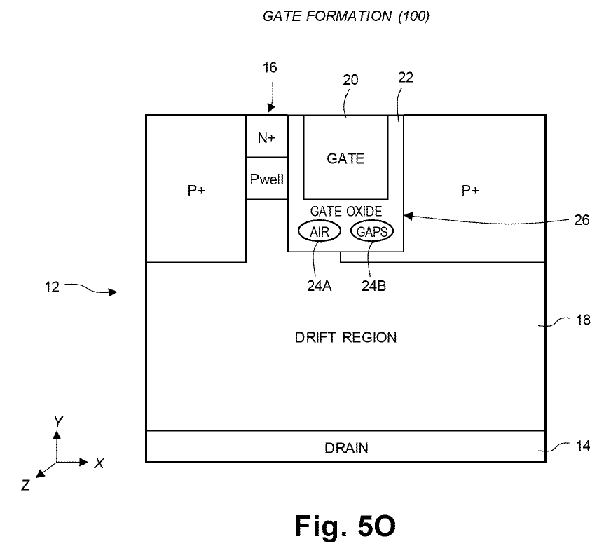

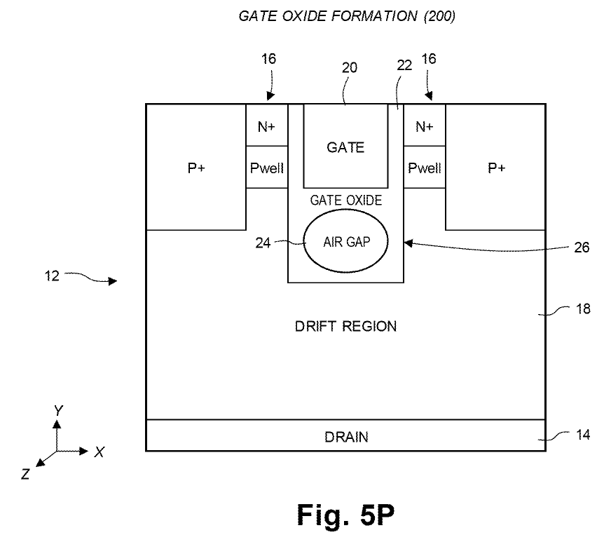

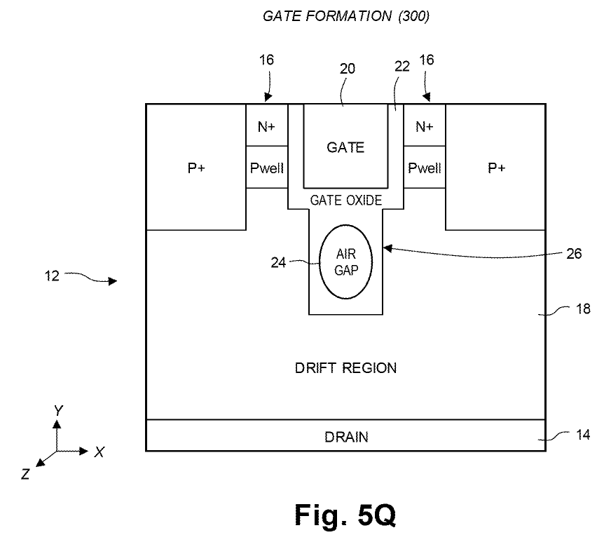

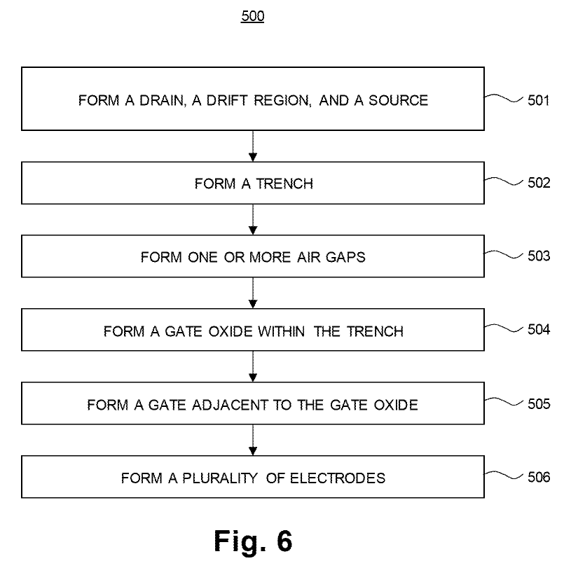

Referring to FIGS. 5A-5Q, portions of the MOSFET 100, 200, 300 are shown during various operations of a method 500 for fabricating the MOSFET 100, 200, 300 to include a gate oxide having formed therein one or more air gap(s). In addition, each operation of the method 500 may be listed in a respective one of a plurality of blocks shown in FIG. 6. Each operation discussed may include numerous sub operations.

Referring to block 501 and FIGS. 5A and 5B, a drain 14, a drift region 18, and a source 16 are formed. The drain 14 and the drift region 18 may be formed in a stack utilizing various deposition techniques for epitaxial crystal growth, although certain aspects contemplate alternative means for providing the drain and volume of semiconductor material. For example, a substrate forming the drain may be provided and the volume of semiconductor material 202 may then be epitaxially grown on the substrate. The semiconductor material (that forms a portion of the volume of semiconductor material) may be grown to a height of a top of the drift region 18. Again, the drain 14 may be formed by providing an N+ substrate below the first (bottom) end of the volume of semiconductor material. The volume of semiconductor material 12 (including the drift region 18) may be epitaxially grown with the N- doping concentration, although alternative examples contemplate implanting the semiconductor material with N- material.

In examples of the MOSFET 100 with reference to FIG. 5A, the left and right doped P+ regions may be implanted into the left and right sides of the body 12 so as to extend from the second (top) end. The P well may be implanted between the left and right P+ doped regions, and the source 16 is formed by implanting N+ material between a portion of the P well and the second (top) end of the body 12.

In examples of the MOSFET 200, 300 with reference to FIG. 5B, the left and right doped P+ regions may be implanted into the left and right sides of the body 12 so as to extend from the second (top) end. The source 16 may be formed by implanting a doped material (such as N+ material) between the doped regions. The P well may be formed by the implantation (e.g., of P material) at a depth (along the Y dimension) below the source 16.

Referring to block 502 and FIGS. 5C, 5D, 5E, and 5F, a trench 26 is formed. In examples of the MOSFET 100, 200 with reference to FIGS. 5C and 5D, the trench 26 is formed by etching, such as a dry etch, a portion of the body 12 at the second, or top, end thereof along a roughly central longitudinal axis and to a depth (along the Y dimension) that is greater than the combined depth of the source 16 and P well. The trench 26 has spaced-apart left and right side surfaces, with a bottom surface positioned therebetween at an orthogonal angle to the side surfaces.

In examples of the MOSFET 300 with reference to FIG. 5E, the top section of the trench 26 is formed by applying a first etch, such as a dry etch, to a portion of the body 12 at the second end thereof along a roughly central longitudinal axis and to a depth (along the Y dimension) that may be less than a depth of the first and second doped (P+) regions but that is greater than the lowermost margin of the P well. The top section of the trench 26 has spaced-apart first left and first right side surfaces, with a first bottom surface positioned therebetween at an orthogonal angle to the first left and first right side surfaces. With reference to FIG. 5F, the bottom section of the trench 26 is formed in the drift region 18 near the center of the body 12 along a roughly central longitudinal axis and to a depth which may be greater than a depth of first and second doped (P+) regions. The bottom section of the trench 26 has spaced-apart second left and second right side surfaces, with a second bottom surface positioned therebetween at an orthogonal angle to the second left and second right side surfaces. The bottom section of the trench 26 may be formed by depositing first and second nitride blocks 34A, 34B along the first left and right side surfaces of the top trench section, respectively. A second etch is applied to the first bottom surface of the trench 26 along an area thereof not covered by the first and second nitride blocks 34A, 34B. This forms the bottom section of the trench 26 to have a width that is less than a width of the top section of the trench 26.

Referring to block 503 and FIGS. 5G, 5H, 5I, 5J, and 5K, one or more air gap(s) is formed. It will be appreciated that formation of the air gap(s) 24 is part of the operation of forming the gate oxide 22 (see block 504). In examples of the MOSFET 100 with reference to FIG. 5G, the trench 26 is filled with a third nitride block 36 and a first oxide 38. The third nitride block 36 has a generally rectangular cuboid shape. The first oxide 38 has a left side section and a spaced-apart right side section which are each connected to a bottom section, positioned therebetween. The first oxide 38 is deposited within the trench 26 such that the left side section of the first oxide 38 extends along the left side surface of the trench 26, the right side section of the first oxide 38 extends along the right side surface of the trench 26, and the bottom section of the first oxide 38 extends along the bottom surface of the trench 26. The left side section, the right side section, and the bottom section of the first oxide 38 form a generally rectangular cuboid shaped cavity in which the third nitride block 36 is deposited. The first oxide 38 may be formed entirely or partly from or include materials with a low dielectric constant k (approximately equal to four (4)).

With reference to FIG. 5H, a portion of the first oxide 38 is removed by etching. The left side section and the right side section are each removed as well as a portion of the bottom section (underneath the third nitride block 36). The remainder of the first oxide 38 undercuts the third nitride block 36 so as to present a lateral dimension (or width) that is less than the lateral dimension of the bottom surface of the trench 26 (with the lateral dimension of the bottom surface being defined between the side surfaces of the trench). The remainder of the first oxide 38 thereby forms a portion of the bottom section of the gate oxide 22. In addition, there is first space on the left side of the bottom section of the gate oxide 22 and a second space on the right side of the bottom section of the gate oxide 22.

With reference to FIG. 5I, the nitride block 36 is removed (e.g., by etching) and a second oxide 40 is deposited. The second oxide 40 may be entirely or partly formed from or include materials with a low dielectric constant k (approximately equal to four (4)) and is deposited (under atmospheric pressure or less than atmospheric pressure) onto the bottom section of the gate oxide 22 such that it overlays the bottom section of the gate oxide 22 as well as the first space and the second space, which thus forms the first air gap 24A in the first space and the second air gap 24B in the second space. Furthermore, the second oxide 40 forms the remainder of the bottom section of the gate oxide 22.

In examples of the MOSFET 200 with reference to FIG. 5J, the bottom section of the gate oxide 22 and the air gap 24 are formed. Oxide may be deposited (under atmospheric pressure or less than atmospheric pressure) along the lower portions of the left and right side surfaces and the bottom surface of the trench 26. As the oxide builds on the surfaces, the air gap 24 may form. The bottom section of the gate oxide 22 may be formed from or include materials with a low dielectric constant k (approximately equal to four (4)).

In examples of the MOSFET 300 with reference to FIG. 5K, the bottom section of the gate oxide 22 and the air gap 24 are formed. Oxide may be deposited (under atmospheric pressure or less than atmospheric pressure) along the left and right side surfaces and the bottom surface of the bottom section of the trench 26. As the oxide builds on the surfaces, the air gap 24 may form. The bottom section of the gate oxide 22 may be formed from or include materials with a low dielectric constant k (approximately equal to four (4)).

Referring to block 504 and FIGS. 5L, 5M, and 5N, formation of the gate oxide 22 continues within the trench 26. In examples of the MOSFET 100, 200 with reference to FIGS. 5L and 5M, the left side section and the right side section of the gate oxide 22 are grown. The left side section extends along the left side surface of the trench 26. And, the right side section extends along the right side surface of the trench 26. In examples of the MOSFET 300 with reference to FIG. 5N, the top section of the gate oxide 22 is grown. The left side wall extends along the left side surface of the top section of the trench 26, and the right side wall extends along the right side surface of the top section of the trench 26. Further, gate oxide is also grown along the small bottom wall surfaces of the top trench section, which remain after the lower trench section is formed and extend between the respective side surface of the top section and the bottom trench section. The gate oxide grown along the small bottom wall surfaces may also extend continuously therebetween to overlie the gate oxide already formed in the bottom trench section.

Referring to block 505 and FIGS. 5O, 5P, and 5Q, a gate 20 is formed adjacent to, and in contact with, the gate oxide 22. The gate 20 is deposited in the generally rectangular cuboid shaped cavity formed by the left side wall, the right side wall, and the bottom section of the gate oxide 22. The gate 20 is formed from or includes polysilicon, a metal or alloy of metals, or other suitable material.

Referring to block 506 and FIGS. 1, 2, and 3, a plurality of electrodes is formed. The electrodes include a gate electrode 28 to provide electrical contact with the gate 20, a source electrode 30 to provide electrical contact with the source 16, and a drain electrode 32 to provide electrical contact with the drain 14. Each electrode 28, 30, 32 may be formed by depositing metal or a metal alloy on the respective gate 20, source 16, and drain 14.

Additional processing may be performed if desired.

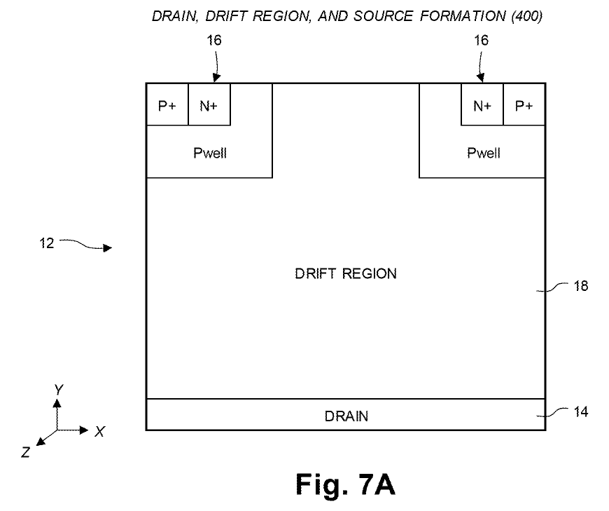

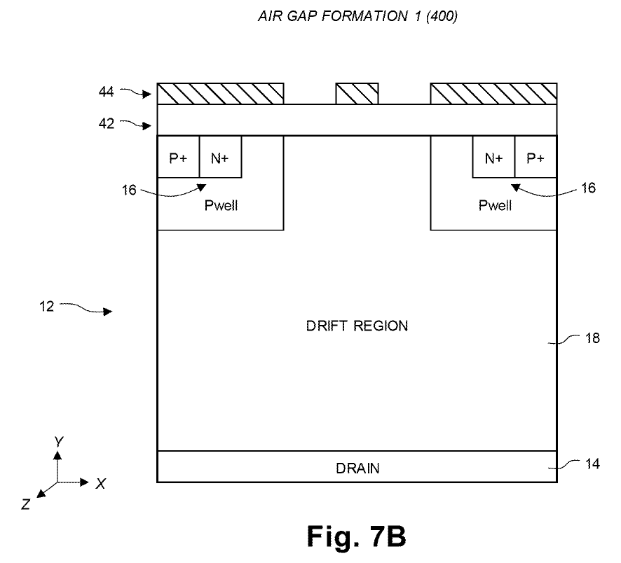

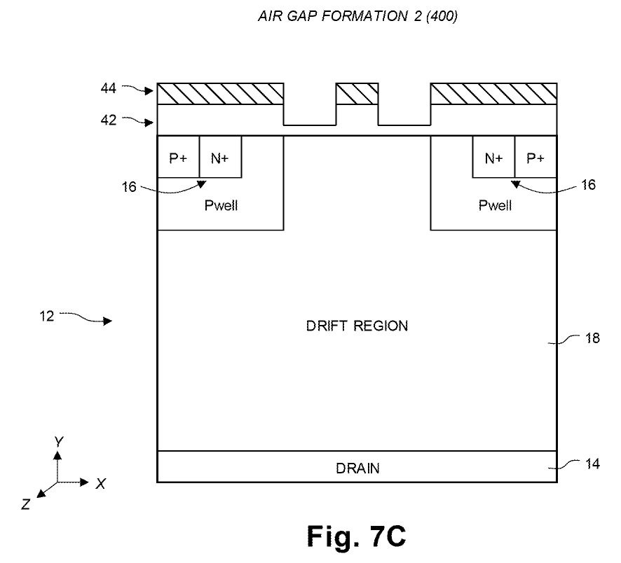

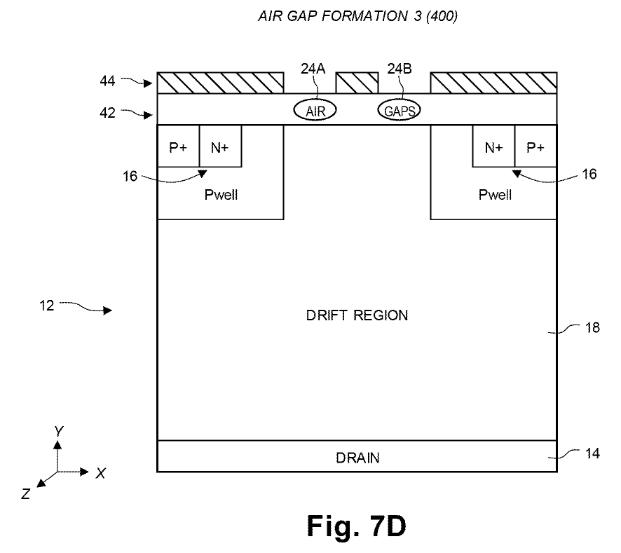

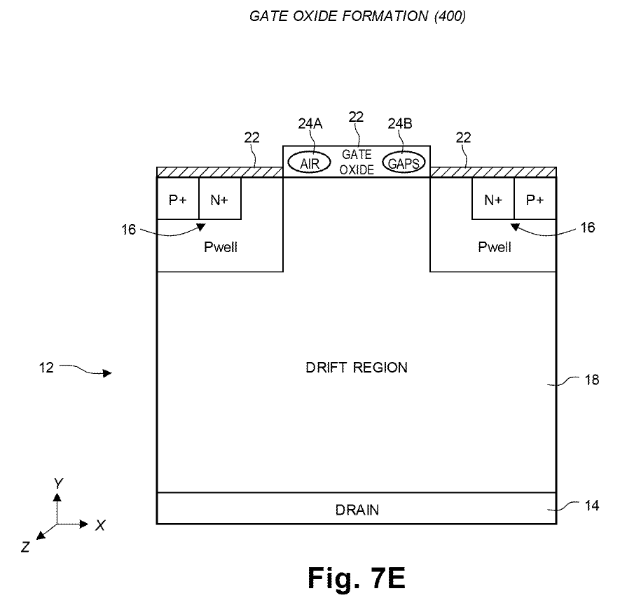

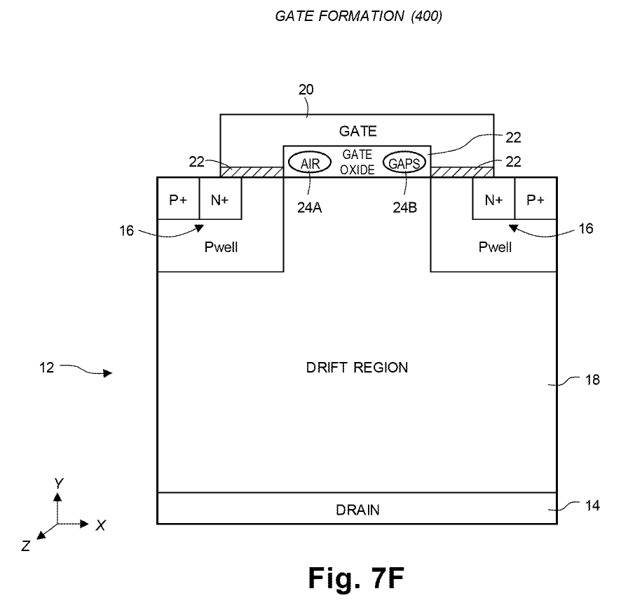

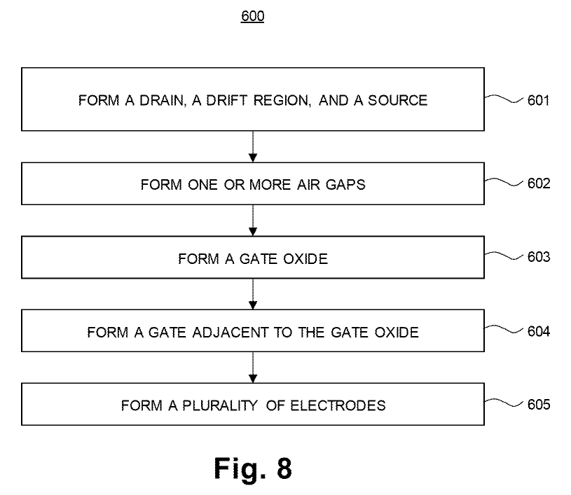

Referring to FIGS. 7A-7F, portions of the MOSFET 400 are shown during various operations of a method 600 for fabricating the MOSFET 400 to include a gate oxide having formed therein one or more air gap(s). In addition, each operation of the method 600 may be listed in a respective one of a plurality of blocks shown in FIG. 8. Each operation discussed may include numerous sub operations.

Referring to block 601 and FIG. 7A, a drain 14, a drift region 18, and a source 16 are formed. The drain 14 and the drift region 18 may be formed in a stack utilizing various deposition techniques for epitaxial crystal growth, although certain aspects contemplate alternative means for providing the drain and volume of semiconductor material. For example, a substrate forming the drain may be provided and the volume of semiconductor material 202 may then be epitaxially grown on the substrate. The semiconductor material (that forms a portion of the volume of semiconductor material) may be grown to a height of a top of the drift region 18. Again, the drain 14 may be formed by providing an N+ substrate below the first (bottom) end of the volume of semiconductor material. The volume of semiconductor material 12 (including the drift region 18) may be epitaxially grown with the N- doping concentration, although alternative examples contemplate implanting the semiconductor material with N- material.

The wells (which may be formed of a P material) are implanted along the left and right sides of the body volume of semiconductor material. A left side section of the source 16 (which may be an N+ material) and a left side doped region (or body contact which may be a P+ material) may be formed by implantation within the left P-well. A right side section of the source 16 (which may be an N+ material) and a right side doped region (or body contact which may be a P+ material) may be formed by implantation within the right P-well.

Referring to block 602 and FIGS. 7B, 7C, and 7D, one or more air gap(s) 24 are formed. It will be appreciated that formation of the air gap(s) 24 is part of the operation of forming the gate oxide 22 (see block 604). With reference to FIG. 7B, an oxide layer 42 is deposited on an upper surface of the body 12. The oxide layer 42 has a thickness (along the Y dimension) equal to or greater than the thickness of the middle thick oxide section of the gate oxide 22. The oxide layer 42 may be formed from materials with a low dielectric constant k (approximately equal to four (4)). A mask 44 is applied to an upper surface of the oxide layer 42. The mask 44 includes a plurality of openings, with each opening positioned in a location for a respective one of the air gaps 24. In an alternative example, the mask 44 may include just a single opening in order to form just a single air gap 24.

With reference to FIG. 7C, the oxide layer 42 is etched in the locations of the openings. A lowermost portion of the oxide layer 42 is left on the upper surface of the body 12 in each location.

With reference to FIG. 7D, additional oxide 42 material is deposited (under atmospheric pressure or less than atmospheric pressure) in the openings of the mask 44. The additional oxide material 42 forms a bubble in each opening which creates the first and second air gaps 24A, 24B.

Referring to block 603 and FIG. 7E, formation of the gate oxide 22 continues. The thick oxide section of the gate oxide 22 is formed by etching the oxide layer 42 over the first and second sections of the source 16. The left side thin oxide section is formed by growing oxide over a portion of the first section of the source 16. The right side thin oxide section is formed by growing oxide over a portion of the second section of the source 16. In some examples, operations of blocks 602 and 603 may be combined to concurrently form the air gap(s) 24 and the left and right thin oxide sections of the gate oxide 22. The left and right endmost portions of the thin gate oxide are etched so as to permit electrical connection (e.g., via electrodes) to the source 16 and P+ body contacts (compare FIGS. 7E and 7F).

Referring to block 604 and FIG. 7F, a gate 20 is formed adjacent to, and in contact with, the gate oxide 22. The gate 20 is formed by depositing polysilicon, or other suitable semiconductor or metallic material, onto the gate oxide 22. Typically, the polysilicon is deposited on the entire upper surface of the body 12 (a so-called “full coat”). Then, using a mask to cover the region of the gate 20, the remainder of the polysilicon is etched.

Referring to block 605 and FIG. 4, a plurality of electrodes is formed. The electrodes include a gate electrode 28 to provide electrical contact with the gate 20, a source electrode 30 to provide electrical contact with the source 16, and a drain electrode 32 to provide electrical contact with the drain 14. Each electrode 28, 30, 32 is formed by depositing metal or a metal alloy on the respective gate 20, source 16, and drain 14.

Additional processing may be performed if desired.

### GENERAL CONSIDERATIONS

Although described herein with regard or in relation to one or more particular kinds of electronic devices (e.g., a trench-type or planer-type metal oxide semiconductor field-effect transistor), the technology may be more broadly applicable to one or more other kinds of electronic devices as well.

Additionally, the various example materials identified herein may, in some aspects, be replaced and/or supplemented with substantially any other suitable material. For example, gate material may include polysilicon, a metal or alloy of metals, or other suitable material; gate oxide or dielectric may include silicon dioxide (SiO2), aluminum oxide (Al2O3), hafnium dioxide (HfO2), silicon nitride (Si3N4), or other suitable material; and semiconductor material may include silicon (Si), silicon carbide (SiC), gallium nitride (GaN), zinc oxide (ZnO), or other suitable material.

Additionally, in general, unless otherwise specified or unless one with ordinary skill in the art would understand otherwise, doping characterized as "++" (e.g., P++) will have a relatively higher concentration of dopants than "+" (e.g., P+) doping, "+" doping will have a relatively higher concentration than "-well" (e.g., P-well) doping, and "-well" doping will have a relatively higher concentration of doping than "-" (e.g., P-) doping. In general, doping concentrations (typically measured in parts-per-cubic-centimeter) for contact implants (e.g., sources, drains, body contacts) may be approximately between 5x10^18 and 1x10^22; doping concentrations for channel and threshold forming implants (e.g., P-wells) may be approximately between 5x10^15 and 5x10^17; doping concentrations for shielding implants may be approximately between 5x10^17 and 5x10^19; doping concentrations for conductivity improvement implants (e.g., N- doping in the junction field-effect transistor neck region of a metal oxide semiconductor field-effect transistor) may be approximately between 1x10^17 and 1x10^19; and doping concentrations for drift regions (e.g., N doping) may be approximately between 1x10^15 and 1x10^16. In some examples, the doping concentration range for the drift region may be widened, for example to approximately between 1x10^14 and 1x10^18.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

Throughout this specification, references to “one example,” “an example,” or “examples” mean that the feature or features being referred to are included in at least one example of the technology. Separate references to “one example,” “an example,” or “examples” in this description do not necessarily refer to the same example and are also not mutually exclusive unless so stated or except as will be readily apparent to those skilled in the art from the description. For example, a feature, structure, act, etc. described in one example may also be included in other examples, but is not necessarily included. Thus, the current technology can include a variety of combinations, integrations, or both, of the examples described herein.

Although the present application sets forth a detailed description of numerous different examples, it should be understood that the legal scope of the description is defined by the words of the claims set forth at the end of this patent and equivalents. The detailed description is to be construed as illustrative only and does not describe each possible example since describing each possible example would be impractical. Numerous alternative examples may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the examples illustrated in the attached drawing figures, it is noted that equivalents may be employed and substitutions made herein without departing from the scope of the technology as recited in the claims.

Having thus described various examples of the technology, what is claimed as new and desired to be protected by Letters Patent includes the following:

1. A metal oxide semiconductor field effect transistor (MOSFET) comprising:
a body formed from semiconductor material to present opposite, vertically spaced first and second ends;
a drain;
a source adjacent the second end of the body, with a drift region being defined by the body between the source and the drain;
a gate adjacent the second end of the body proximal to the source;
a gate oxide in contact with the gate; and
an air gap within the gate oxide.

2. The MOSFET of claim 1,
the gate oxide including a first oxide portion that is located between and contacts the gate and the drift region,
the air gap being positioned in the first oxide portion of the gate oxide.

3. The MOSFET of claim 2,
the drain being located at the first end of the body,
the first oxide portion and air gap being located beneath the gate.

4. The MOSFET of claim 3,
the gate oxide including a second oxide portion that is located between and contacts the gate and the source.

5. The MOSFET of claim 4,
the second oxide portion being devoid of an air gap.

6. The MOSFET of claim 4, comprising:
a trench extending from the second end into the body,
the gate oxide lining the trench, and the gate being positioned in the trench interiorly of the gate oxide.

7. The MOSFET of claim 6,
the trench including a trench bottom surface spaced from the second end of the body,
the trench further including laterally spaced apart left and right trench side surfaces, each of which extends between the trench bottom surface and the second end.

8. The MOSFET of claim 7,
the first oxide portion being located along the trench bottom surface.

9. The MOSFET of claim 8,
the source being located along the left trench side surface,
the second oxide portion being located along the left trench side surface; and
a well having an opposite dopant polarity than the source and being located along the left trench side surface beneath the source.

10. The MOSFET of claim 8,
the source including left and right source sections, each of being located along the respective trench side surface,
the second oxide portion being located along the left trench side surface and the right trench side surface; and
a well having an opposite dopant polarity than the source and being located along each of the trench side surfaces beneath the respective source section.

11. The MOSFET of claim 6,
the trench including a top trench section positioned at the second end of the body and a bottom trench section beneath the top trench section,
the bottom trench section having a lateral width that is less than a lateral width of the top trench section,
the first oxide portion being located in the bottom trench section.

12. The MOSFET of claim 11,
each of the trench sections including laterally spaced apart left and right trench side surfaces, with the trench side surfaces of the top trench section extending from the second end of the body,
the second oxide portion being located along the left and right trench side surfaces of the top trench section.

13. The MOSFET of claim 11,
the gate being located in the top trench section,
the gate oxide including an oxide layer located within the top trench section,
the oxide layer underlying the gate and extending between the left and right trench side surfaces of the top trench section.

14. The MOSFET of claim 4,
the second end of the body being planar,
the source being located at the second end of the body,
the drift region extending to the second end of the body and being spaced laterally from the source,
the gate being located above the second end of the body.

15. The MOSFET of claim 14, comprising:
a well having an opposite dopant polarity than the source and being located at the second end of the body between the source and the drift region,
the second oxide portion overlying the well and at least a portion of the source,
the first oxide portion extending laterally from the second oxide portion and overlying the drift region.

16. The MOSFET of claim 4,
the air gap including multiple, isolated portions.

17. The MOSFET of claim 4,
the first oxide portion being formed at least in part of a material having a first dielectric constant,
the second oxide portion being formed of a material having a second dielectric constant,
the first dielectric constant being less than second dielectric constant.

18. The MOSFET of claim 1, comprising:
a trench extending from the second end into the body,
the gate oxide lining the trench,
the trench including a top trench section positioned at the second end of the body and a bottom trench section beneath the top trench section,
the gate being located in the top trench section,
the air gap being located in the bottom trench section,
the bottom trench section having a lateral width that is less than a lateral width of the top trench section.

19. The MOSFET of claim 1,
the air gap including multiple, isolated portions.

20. The MOSFET of claim 19,
the air gap including less than five (5) total isolated portions, each of which has a minimum cross-sectional dimension of at least twenty nanometers (20 nm).
